(19) United States
(12) Patent Application Publication
(10) Pub. No.: US 2024/0234573 A1
(43) Pub. Date: Jul. 11, 2024

(54) MICROELECTRONIC FET DEVICE INCLUDING LARGE CONTACT SURFACES BETWEEN THE CONDUCTION CHANNEL AND THE SOURCE AND DRAIN REGIONS

(71) Applicant: COMMISSARIAT A L'ENERGIE ATOMIQUE ET AUX ENERGIES ALTERNATIVES, Paris (FR)

(72) Inventors: Sylvain BARRAUD, Grenoble Cedex (FR); Rémi COQUAND, Grenoble Cedex (FR); Shay REBOH, Grenoble Cedex (FR)

(73) Assignee: COMMISSARIAT A L'ENERGIE ATOMIQUE ET AUX ENERGIES ALTERNATIVES, Paris (FR)

(21) Appl. No.: 18/393,094

(22) Filed: Dec. 21, 2023

(30) Foreign Application Priority Data
Dec. 22, 2022 (FR) 22 14258

(51) Int. Cl. H01L 29/78; H01L 21/8234; H01L 27/088; H01L 29/08; H01L 29/51; H01L 29/66; H10B 51/30

(52) U.S. Cl. CPC H01L 29/78391; H01L 21/823437; H01L 27/088; H01L 29/0847; H01L 29/516; H01L 29/6656; H10B 51/30

(57) ABSTRACT

A FET microelectronic device comprising:
a semiconductor layer a first area of which forms a channel;
a gate and a gate dielectric layer or a ferroelectric memory layer, arranged against the first area;
dielectric spacers arranged against sidewalls of the gate;
source/drain regions electrically coupled to the first area via second areas of the active layer extending between the source/drain regions and the dielectric spacers;
wherein the second areas form a continuous layer with the first area, and the first area forms a semiconductor portion such that the gate covers several distinct faces of the semiconductor portion.

### TECHNICAL FIELD

The invention relates to the field of microelectronic devices applied to advanced CMOS technologies. In particular, the invention covers microelectronic devices of the FET type (“Field-Effect Transistor” in English), in particular of the FinFET type (“Fin Field-Effect Transistor” in English) or of the FeFET type (“Ferroelectric Field Effect Transistor” in English, or ferroelectric-effect transistor), in particular based on two-dimensional materials, or 2D materials, or semiconductor oxides, as well as making of such microelectronic devices.

### PRIOR ART

Electronics miniaturisation is constantly increasing, but the industry now approaches the scale limit for conventional materials such as silicon. Recently, 2D materials have emerged as promising candidates for use in miniature electronic and optoelectronic devices because of their unique properties and the very small thickness of the layers of these materials which could be made as a unique layer of atoms or molecules.

The document by K. P. O'Brien et al., “Advancing 2D Monolayer CMOS Through Contact, Channel and Interface Engineering,” 2021 IEEE International Electron Devices Meeting (IEDM), 2021, pp. 7.1.1-7.1.4, suggests making a MOSFET transistor by integrating a MoS₂ layer to form the conduction channel. This layer is connected to two metallic source and drain regions based on gold, palladium, TiN, tungsten or nickel. The rear gate is formed by a doped silicon layer positioned at the rear face beneath a dielectric layer based on SiO₂, HfO₂ or Al₂O₃.

In order to overcome the constraints related to the deposition of the metallic materials of the source and drain regions over the 2D material, it is possible to form these regions not over the upper face of the 2D material layer, but against the sidewalls of the 2D material layer. Nonetheless, this configuration, so-called “side contact”, is problematic because the contact surface between the 2D material layer and the source and drain regions is small, which creates considerable contact resistances at the interfaces between the 2D material layer and the source and drain regions.

The document US 2022/045176 A1 describes several methods for making “gate-last” type FET transistors, wherein silicon portions serve as a support for the deposition of a 2D material layer. Besides the drawbacks related to the fact that the completed transistors have “side contact” type channel/source-drain interfaces, the silicon portions used to deposit the 2D material form a potential barrier at the interface with the 2D material, which is not desirable because a part for charges transport could be made in these silicon portions rather than in the 2D material.

### DISCLOSURE OF THE INVENTION

The present invention aims to provide a FET-type microelectronic device whose structure is compatible with any type of semiconductor material including 2D materials or other semiconductor oxide type materials, and devoid of the drawbacks of a “side contact” configuration.

For this purpose, the present invention provides a FET microelectronic device comprising at least:
a substrate;
a semiconductor layer comprising at least one first area forming a semiconductor portion in the form of a fin and serving as an electrical conduction channel of the FET microelectronic device;
an electrostatic control gate;
a gate dielectric layer or a ferroelectric memory layer, arranged between the electrostatic control gate and the first area of the semiconductor layer while covering several distinct faces of the first area of the semiconductor layer;
dielectric spacers arranged against sidewalls of the electrostatic control gate;
source/drain regions in the form of fins, electrically coupled to the first area of the semiconductor layer via second areas of the semiconductor layer, the second areas of the semiconductor layer extending between the source/drain regions and the dielectric spacers;

and wherein the second areas of the semiconductor layer are not arranged directly against the electrostatic control gate and form a continuous layer with the first area. The proposed microelectronic device is based on a FET-type architecture including no “side contact” type interface between the channel and the source/drain regions thanks to the second areas of the semiconductor layer achieving electrical coupling between the channel formed by the first area of the semiconductor layer and the source/drain regions. These second areas of the semiconductor layer, which extend against at least part of the lateral walls, or sidewalls, of the source/drain regions, form a large contact surface with source/drain regions, which allows reducing the contact resistances of the source/drain regions. Thus, the electrical current circulating in the channel is not reduced because of these contact resistances, which does not reduce the performances of the device.

In addition, with the proposed architecture, the semiconductor layer may be made just before making the source/drain regions, or just before the metallic deposition of the source/drain regions. Thus, the semiconductor layer whose first area is intended to form the conduction channel is not deteriorated by the steps related to making of the source/drain regions. This is particularly advantageous when the semiconductor layer includes a 2D material.

Furthermore, making of such a device does not require keeping silicon portions for depositing the semiconductor layer intended to form the channel, thereby eliminating the problem of potential barrier at the interface with the material of the semiconductor layer. In the case where the device includes the gate dielectric layer, the device may correspond to a FinFET type transistor. In the case where the device includes the ferroelectric memory layer, the device may correspond to a FeFET-type memory device.

The semiconductor layer may include a two-dimensional material or any other semiconductor material deposited for example by MOCVD (“Metal Organic Chemical Vapor Deposition” in English), CVD (“Chemical Vapor Deposition” in English) or ALD (“Atomic Layer Deposition” in English). In this case, the microelectronic device may be made with very small dimensions. In particular, the semiconductor layer may include at least one 2D material and/or a semiconductor oxide type material.

The electrostatic control gate and the gate dielectric layer, or the electrostatic control gate and the ferroelectric memory layer, may together cover several distinct faces of the semiconductor portion.

Advantageously, the FET microelectronic device may be such that:
each of the source/drain regions is arranged in a cavity comprising lateral walls formed at least by the dielectric spacers and by an insulating dielectric material;
the second areas of the semiconductor layer cover at least one part, and preferably all, of the walls of the cavities in which the source/drain regions.

In the configuration hereinabove, the contact surfaces of the source/drain regions with the semiconductor layer are maximised thanks to the use of the surface of the walls of the cavities, and advantageously the entirety of the surface of the walls of the cavity, to form the contact between the second areas of the semiconductor layer and the source/drain regions, which allows having very low contact resistances of the source/drain regions, and therefore a higher current flowing through the conduction channel of the device.

The FET microelectronic device may further include at least one dielectric portion surrounded by the first area of the semiconductor layer.

Alternatively, it is possible that the first area of the semiconductor layer does not surround any dielectric portion.

The semiconductor layer may include several first areas forming several distinct semiconductor portions in the form of fins, arranged over the substrate and such that the gate dielectric layer or the ferroelectric memory layer is arranged between the electrostatic control gate and each of the first areas of the semiconductor layer while together covering several distinct faces of each of the first areas of the semiconductor layer.

Advantageously, the invention could be applied to make CMOS components for 5 nm and sub-5 nm technological nodes.

The invention also relates to a method for making a FET microelectronic device, comprising at least:
a) making at least one temporary material portion over a substrate, then
b) making, at least over the temporary material portion, at least one electrostatic control gate and dielectric spacers arranged against sidewalls of the electrostatic control gate, the electrostatic control gate covering several distinct faces of the temporary material portion, then
c) etching the temporary material portion, then
d) making a semiconductor layer including a two-dimensional material or any other semiconductor material deposited by MOCVD, CVD or ALD, the semiconductor layer comprising at least one first area forming a semiconductor portion in the form of a fin arranged over the substrate and configured to serve as an electrical conduction channel of the FET microelectronic device, arranged beneath the electrostatic control gate and the dielectric spacers in at least one location formed by etching of the temporary material portion, and such that the semiconductor layer extends, with no discontinuity with the first area, while forming second areas covering at least part of the sidewalls of the dielectric spacers and which are not arranged directly against the electrostatic control gate, then
e) making, over the substrate, source/drain regions in the form of fins, electrically coupled to the first area of the semiconductor layer via the second area of the semiconductor layer, and such that the second areas of the semiconductor layer extend between the source/drain regions and the dielectric spacers.

The method may further include, before implementation of step c), depositing an insulating dielectric material around the dielectric spacers, then etching cavities in the insulating dielectric material such that the cavities comprise at least one lateral wall formed by one of the dielectric spacers, and wherein:
step d) is implemented such that the second areas of the semiconductor layer cover at least part of the lateral walls of the cavities;
step e) is implemented such that each of the source/drain regions is arranged in one of the cavities.

In an advantageous configuration:
step a) may include making several temporary material portions over the substrate, and
step b) may be implemented such that the electrostatic control gate covers several distinct faces of each of the temporary material portions, and
step c) includes etching all of the temporary material portions, and
step d) may be implemented such that several first areas of the semiconductor layer are arranged in locations formed by etching of the temporary material portions, the first areas of the semiconductor layer forming several semiconductor portions arranged over the substrate and such that the electrostatic control gate covers several distinct faces of each of the first areas of the semiconductor layer.

The method may further include a step of depositing a gate dielectric layer or a ferroelectric memory layer implemented:
between steps a) and b), over the temporary material portion, the electrostatic control gate being made afterwards over the gate dielectric layer or the ferroelectric memory layer, and/or
between steps c) and d), beneath the electrostatic control gate and the dielectric spacers, in at least one location formed by etching of the temporary material portion, the semiconductor layer being made afterwards by covering the gate dielectric layer or the ferroelectric memory layer.

The invention also relates to a method for making a FET microelectronic device, comprising at least:
a) making at least one temporary material portion over a substrate, then
b) making, at least over the temporary material portion, at least one temporary gate and dielectric spacers arranged against sidewalls of the temporary gate, the temporary gate covering several distinct faces of the temporary material portion, then
c) etching the temporary material portion, then
d) making a semiconductor layer including a two-dimensional material or any other semiconductor material deposited by MOCVD, CVD or ALD, the semiconductor layer comprising at least one first area forming a semiconductor portion in the form of a fin arranged over the substrate and configured to serve as an electrical conduction channel of the FET microelectronic device, arranged beneath the temporary gate and the dielectric spacers in at least one location formed by etching of the temporary material portion, and such that the semiconductor layer extends, with no discontinuity with the first area, while forming second areas covering at least part of the sidewalls of the dielectric spacers and which are not arranged directly against the temporary gate, then
e) etching the temporary gate, and making at least one electrostatic control gate instead of the temporary gate, then
f) making, over the substrate, source/drain regions in the form of fins, electrically coupled to the first area of the semiconductor layer via the second area of the semiconductor layer, and such that the second areas of the semiconductor layer extend between the source/drain regions and the dielectric spacers.

In this case, the method may further include, before implementation of step c), depositing an insulating dielectric material around the dielectric spacers, then etching cavities in the insulating dielectric material such that the cavities comprise at least one lateral wall formed by one of the dielectric spacers, and wherein:
step d) is implemented such that the second areas of the semiconductor layer cover at least part of the lateral walls of the cavities;
step e) is implemented such that each of the source/drain regions is arranged in one of the cavities.

Furthermore, the method may be such that:
step a) includes making several temporary material portions over the substrate, and
step b) is implemented such that the temporary gate covers several distinct faces of each of the temporary material portions, and
step c) includes etching all of the temporary material portions, and
step d) is implemented such that several first areas of the semiconductor layer are arranged in locations formed by etching of the temporary material portions, the first areas of the semiconductor layer forming several semiconductor portions arranged over the substrate and such that the temporary gate covers several distinct faces of each of the first areas of the semiconductor layer.

The method may further include a step of depositing a gate dielectric layer or a ferroelectric memory layer implemented:
during step e), over the first area of the semiconductor layer, the electrostatic control gate being made afterwards over the gate dielectric layer or the ferroelectric memory layer, and/or
between steps c) and d), beneath the temporary gate and the dielectric spacers, in at least one location formed by etching of the temporary material portion, the semiconductor layer being made afterwards by covering the gate dielectric layer or the ferroelectric memory layer.

Throughout the entire document, the terms “over” and “under” are used regardless of the space orientation of the element to which this term relates. For example, in the feature “over a face of the first substrate”, this face of the first substrate is not necessarily oriented upwards but could correspond to a face oriented according to any direction. Furthermore, the arrangement of a first element over a second element should be understood as possibly corresponding to the arrangement of the first element directly against the second element, without any intermediate element between the first and second elements, or as possibly corresponding to the arrangement of the first element over the second element with one or more intermediate element(s) arranged between the first and second elements.

Throughout the entire document, the term “layer” may refer to one single layer or to a stack of several layers.

Throughout the entire document, the expression “electrically couple” is used to refer to an electrical connection which could be direct or which could be indirect (i.e. achieved through one or more intermediate electrical elements).

### BRIEF DESCRIPTION OF THE DRAWINGS

The present invention will be better understood upon reading the description of embodiments given for merely indicative and non-limiting purposes with reference to the appended drawings wherein:

FIG. 1 to FIG. 6 schematically illustrate the steps of a method for making the FET microelectronic device, object of the present invention, according to a particular embodiment;

FIG. 7 schematically illustrates a microelectronic device, object of the present invention, according to a variant of the particular embodiment.

Identical, similar or equivalent parts of the different figures described hereinafter bear the same reference numerals so as to facilitate passage from one figure to another.

The different parts illustrated in the figures are not necessarily plotted according to a uniform scale, to make the figures more readable.

The different possibilities (variants and embodiments) should be understood as not being exclusive of one another and could be combined together.

### DETAILED DISCLOSURE OF PARTICULAR EMBODIMENTS

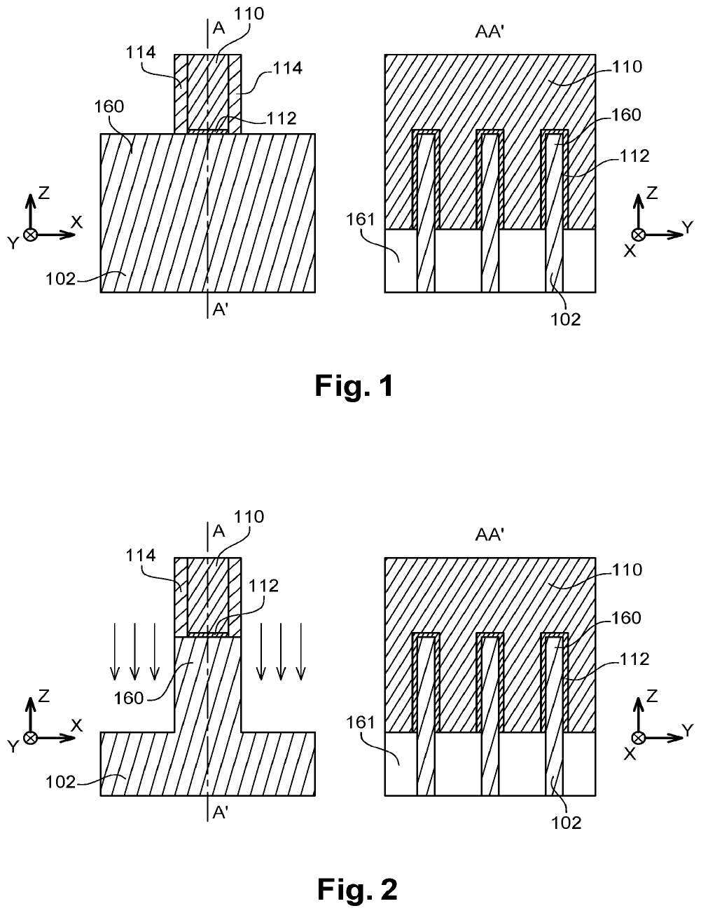

An example of a method for making a FET microelectronic device 100 according to a particular embodiment, corresponding to a FinFET device, is described hereinbelow with reference to FIGS. 1 to 6. In each of these figures, the left-side view is a sectional view in the plane (X,Z), and the right-side view corresponds to a sectional view according to the axis AA′ visible in the left-side view.

In the embodiment described with reference to the figures, the device 100 is made based on a bulk-type substrate 102. The substrate 102 is etched starting from its upper face so as to form, over this face, one ore more temporary material portion(s) 160 whose shape and volume correspond to those desired to form the active area of the device 100. In FIG. 1, three temporary material portions 160 are illustrated.

Alternatively, the substrate 102 may correspond to a SOI substrate, i.e. comprising a silicon superficial layer arranged over a buried dielectric layer comprising for example SiO₂, the buried dielectric layer being arranged over a support layer for example comprising silicon.

Afterwards, a gate dielectric layer 112 and an electrostatic control gate 110 are made and cover several distinct faces of each temporary material portion 160. The sidewalls of the gate 110 are covered with the dielectric spacers 114. Furthermore, the portions 160 are electrically insulated by STI-type (“Shallow Trench Isolation” in English) dielectric insulation regions 161 formed in the substrate 104.

For example, the layer 112 includes a high-K dielectric material (with a high dielectric permittivity) such as HfO₂. Alternatively, this layer 112 may include SiO₂ or Al₂O₃ or any other suitable material or combination of materials.

For example, the electrostatic control gate 110 is made by depositing one or more conductive material(s) over the layer 112, for example a first deposition of a thin TiN layer (a thickness for example equal to 3 nm) over which a tungsten layer with a thickness for example equal to 200 nm is stacked. Alternatively, the gate 110 may include one or more material(s) other than TiN or W, like for example doped polysilicon or any other metal (Mo, etc.).

Furthermore, a material suitable for making the dielectric spacers 114 corresponds for example to SiN, SiCO or SiBCN. The thickness of the deposited layer to make the dielectric spacers 114 is for example comprised between 5 nm and 15 nm.

Afterwards, the portions 160 are anisotropically etched so as to keep only the parts of these portions covered with the gate 104 (cf. FIG. 2). This etching is stopped at the insulating regions 161.

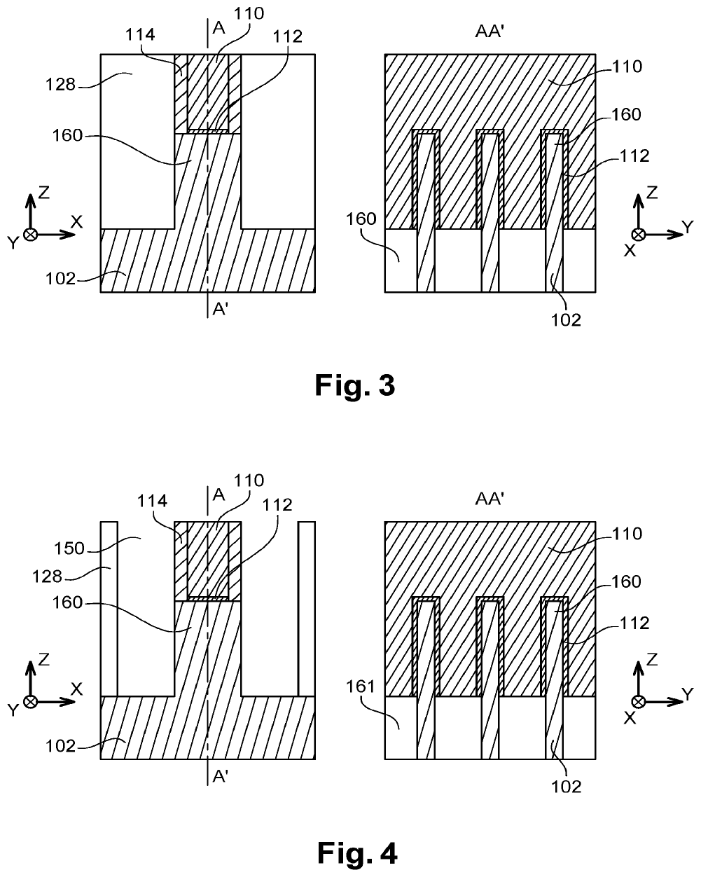

Afterwards, an insulating dielectric material 128, for example SiO₂, is deposited and then planarised with stoppage at the hard mask (not visible in the figures). The insulating dielectric material 128 is deposited with a large thickness, and then a planarisation is implemented until reaching the hard mask. Afterwards, the hard mask is removed for example by wet etching, for example using a diluted H₃PO₄ solution used at a temperature of 110° C. The structure obtained at this stage of the process is illustrated in FIG. 3. Afterwards, receiving cavities 150 are formed. These cavities 150 form locations for making the source and drain regions of the device 100.

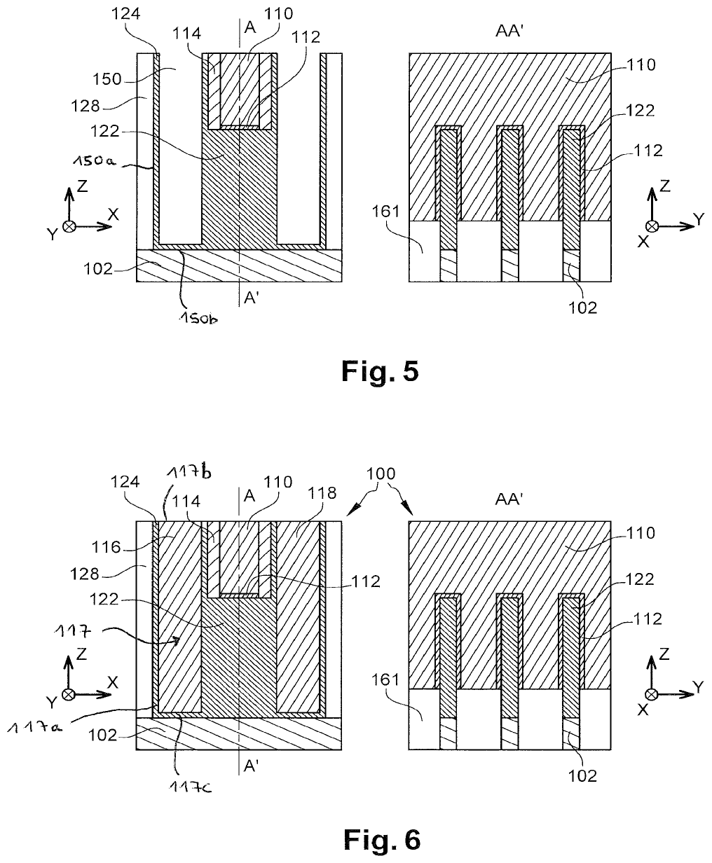

Making these cavities 150 may herein comprise etching the insulating dielectric material 128 (cf. FIG. 4). The cavities 150 comprise lateral walls 150a which are formed by the dielectric spacers 114 and remaining portions of the insulating dielectric material 128. Afterwards, the temporary material portions 160 are etched, then a semiconductor layer 120 is deposited (cf. FIG. 5). First areas 122 of the semiconductor layer 120 form semiconductor portions in the form of fins arranged over the substrate 102 and occupying the spaces formed by etching of the remaining parts of the temporary portions 160 localised beneath the gate 110. The second areas 124 of the semiconductor layer 120 herein entirely cover the lateral walls 150a as well as the bottom 150b of the cavities 150. The semiconductor layer 120 includes at least one 2D semiconductor material, for example a dichalcogenide of transition metals such as MoS₂, or WSe₂, or WS₂, or MoTe₂. It is also possible that the material of the semiconductor layer 120 corresponds to IGZO, In₂O₃, IWO, ITO, or an amorphous semiconductor oxide, or any other suitable semiconductor material deposited by CVD, MOCVD or ALD.

Afterwards, contacts 117 for the source 116 and drain 118 regions are made in the cavities 150 by depositing, in the described example, one or more metal material(s) in the cavities 150. Before this or these metal deposition(s), it is possible to deposit a graphene layer in the cavities 150, this or these metal(s) being deposited afterwards over the graphene layer. In FIG. 6, these source 116 and drain 118 contacts 117 are electrically coupled to the first areas 122 of the semiconductor layer 120 via the second areas 124 of the semiconductor layer 120 which extend against the dielectric spacers 114 as well as against the other lateral walls of the cavities 150. Advantageously, the contacts 117 for the source 116 and drain 118 regions are herein entirely surrounded by the second areas 124 of the semiconductor layer 120 at their lateral sidewalls 117a and a lower end portion 117b located at the bottom 150a of the cavity 150.

The material of these regions deposited outside the cavities 150 is eliminated by implementation of a planarisation with stoppage at the insulating dielectric material 128. Only one upper end portion 117c of the contacts 117 S/D flush with an entrance of the cavity 150 is not surrounded by the semiconductor material layer 120.

Advantageously, the source 116/drain 118 regions include at least one metal material such as gold, palladium, TiN, W, Ni, etc. According to one embodiment, each of the source 116/drain 118 regions includes a TiN layer over which a tungsten portion is formed. Different metals may be used to form the regions 116, 118 in order to favour low contact resistances, like for example: S, Bi, Sn, Pd, Ru, Cu, Ni, Ti, TiN, W, Au, etc. These materials may also be modified later on to improve their properties), for example through a doping step. The obtained device 100 is visible in FIG. 6.

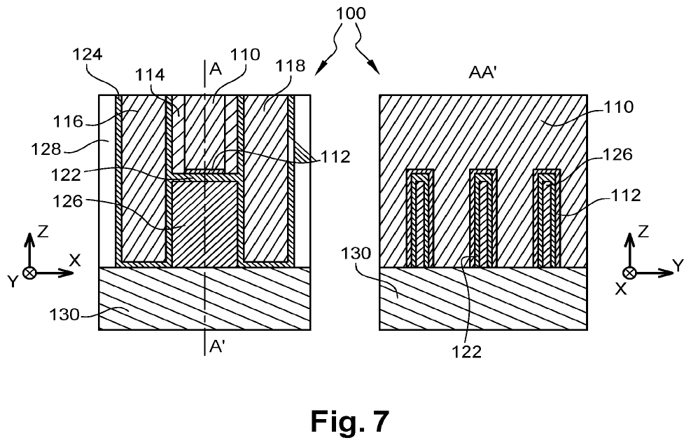

In the previously-described embodiment, the semiconductor layer 120 is such that the space previously occupied by the temporary portion(s) 160 is completely filled with the material of the semiconductor layer 120. Alternatively, it is possible that the semiconductor layer 120 does not completely fill the space(s) previously occupied by the temporary portion(s) 160. In this case, after deposition of the semiconductor layer 120, the remaining space(s) are filled with the dielectric material so as to form one ore more dielectric portion(s) 126 (visible in the example of FIG. 7 described hereinbelow) surrounded by the first area 122 of the semiconductor layer 120. To form this or these portion(s) 126, one ore more dielectric layer(s), comprising for example Al₂O₃ (or HfO₂) and/or SiO₂ (or a low-k dielectric, or with a low dielectric permittivity), are deposited and then isotropically etched so as to keep only portions 126 localised in the remaining spaces.

According to another variant, the substrate 102 may be of the semiconductor-on-insulator type, for example SOI. In this case, the temporary portions 160 are made starting from the semiconductor superficial layer of the substrate 102. The steps implemented to make the device 100 are similar to those previously described with reference to FIGS. 1 to 6 (except the insulating regions 161 which do not have to be made in this variant). The device 100 obtained according to this variant is visible in FIG. 7.

In the different previously-described examples, the second areas 124 of the semiconductor layer 120 cover all of the sidewalls and the bottom walls of the source 116 and drain 118 regions. In general, it is possible that the second areas 124 of the semiconductor layer 120 extend between the source 116 and drain 118 regions and the dielectric spacers 114 and/or against walls of the source and drain regions different from those arranged against the dielectric spacers 114. Furthermore, the walls of the source 116 and drain 118 regions may be covered only partially by the second areas 124 of the semiconductor layer 120.

In the embodiments previously described for the first and second embodiments, the gate dielectric layer 112 and the electrostatic control gate(s) 110 are made over the temporary material portion(s) 160 before making the semiconductor layer 120 (a so-called “gate first” approach). Alternatively, instead of the gate dielectric layer 112 and the electrostatic control gate(s) 110, it is possible to make one or more temporary gate(s) over the temporary material portion(s) 160, then, after making the semiconductor layer 120, etching the temporary gate(s) and making the gate dielectric layer 112 and the electrostatic control gate(s) 110 instead of the etched temporary gate(s) (a so-called “gate last” approach).

In the previously-described embodiments, the gate dielectric layer 112 is made just before making of the electrostatic control gate(s) 110, whether one or more temporary gate(s) have been used or not. Alternatively, it is possible that the electrostatic control gate(s) 110 is/are made without having made the gate dielectric layer 112 beforehand. In this case, the gate dielectric layer 112 may be deposited just before depositing the semiconductor layer 120, at least against the walls of the location(s) obtained by etching the temporary material portion(s) 160. In this case, the layer 112 covers the different walls over which the material of the semiconductor layer 120 is intended to be deposited, thereby homogenising the surfaces, and therefore the interfaces, against which the semiconductor layer 120 is deposited afterwards.

According to another variant, it is possible that the layer 112 is deposited in two different steps: first of all just before making the gate 110 as previously described with reference to FIG. 1, then in the spaces formed by etching of the portions 160 and in the cavities 150, just before deposition of the semiconductor layer 120. In this case, the parts of the layer 112 localised directly above the gate 110 are thicker than the other parts of the layer 112 because these parts cumulate the material thicknesses deposited during the two deposition steps.

In the previously-described examples and variants, the layer 112 includes a dielectric material intended to form the gate dielectrics of the completed devices 100 which correspond to FinFET transistors. Alternatively, it is possible that the layer 112 includes a ferroelectric material such as HfO₂ or HfZrO2, this layer 112 corresponding in this case to a ferroelectric memory layer. The completed devices 100 correspond to microelectronic devices having a FeFET-type memory function. The previously-described different variants of the making of the layer 112 also apply to a layer 112 including a ferroelectric material. Furthermore, when the layer 112 includes a ferroelectric material, the layer 112 is advantageously deposited in the spaces formed by etching of the portions 160 and in the cavities 150, just before deposition of the semiconductor layer 120, or deposited during two different steps as described before. Thus, the ferroelectric material surface formed by the layer 112 is larger than is the case if it were deposited only just before making the gate 110, which reduces variability of the memory in terms of performance.

1. A FET microelectronic device comprising at least:
a substrate;
a semiconductor layer comprising at least one first area forming a semiconductor portion in the form of a fin and serving as an electrical conduction channel of the FET microelectronic device;
an electrostatic control gate;
a gate dielectric layer or a ferroelectric memory layer, arranged between the electrostatic control gate and the first area of the semiconductor layer while covering several distinct faces of the first area of the semiconductor layer;
dielectric spacers arranged against sidewalls of the electrostatic control gate;
source/drain regions, electrically coupled to the first area of the semiconductor layer via second areas of the semiconductor layer, the second areas of the semiconductor layer extending between the source/drain regions and the dielectric spacers;
wherein the second areas of the semiconductor layer are not arranged directly against the electrostatic control gate and form a continuous layer with the first area;
and wherein the semiconductor layer includes a two-dimensional material,
each of the source/drain regions being fitted with a contact, advantageously metallic, arranged in a cavity, the cavity comprising lateral walls and a bottom, the second areas of the semiconductor layer entirely covering the lateral walls and the bottom of the cavity, so that lateral sidewalls and a lower end portion of said contact are entirely surround by the second areas of the semiconductor layer in the cavity.

2. The FET microelectronic device according to claim 1, wherein the electrostatic control gate and the gate dielectric layer together cover several distinct faces of the semiconductor portion.

3. The FET microelectronic device according to claim 1, wherein: each cavity is formed at least by the dielectric spacers (114) and by an insulating dielectric material.

4. The FET microelectronic device according to claim 1, further including at least one dielectric portion surrounded by the first area of the semiconductor layer.

5. The FET microelectronic device according to claim 1, wherein the semiconductor layer includes several first areas forming several distinct semiconductor portions in the form of fins, arranged over the substrate and such that the gate dielectric layer or the ferroelectric memory layer is arranged between the electrostatic control gate and each of the first areas of the semiconductor layer while covering several distinct faces of each of the first areas of the semiconductor layer.

6. The method for making a FET microelectronic device, comprising at least:
a) making at least one temporary material portion over a substrate, then
b) making, at least over the temporary material portion, at least one gate, the gate being an electrostatic control gate or a temporary gate and dielectric spacers arranged against sidewalls of the gate, the gate covering several distinct faces of the temporary material portion, then
c) etching the temporary material portion, then
d) making a semiconductor layer including a two-dimensional material or any other semiconductor material deposited by MOCVD, CVD or ALD, the semiconductor layer comprising at least one first area forming a semiconductor portion in the form of a fin arranged over the substrate and configured to serve as an electrical conduction channel of the FET microelectronic device, arranged beneath the gate and the dielectric spacers in at least one location formed by etching of the temporary material portion, and such that the semiconductor layer extends, with no discontinuity with the first area, while forming second areas covering at least part of the sidewalls of the dielectric spacers and which are not arranged directly against the gate, then
e) making, over the substrate, source/drain regions, electrically coupled to the first area of the semiconductor layer via the second area of the semiconductor layer, and such that second areas of the semiconductor layer extend between the source/drain regions and the dielectric spacers.

7. The method according to claim 6, wherein the gate formed in step b) is an electrostatic control gate, the method further including, before implementation of step c), depositing an insulating dielectric material around the dielectric spacers, then etching cavities in the insulating dielectric material such that the cavities comprise at least one lateral wall formed by one of the dielectric spacers, and wherein:
step d) is implemented such that the second areas of the semiconductor layer cover at least part of the lateral walls of the cavities;
step e) is implemented such that each of the source/drain regions is arranged in one of the cavities.

8. The method according to claim 6, wherein the gate formed in step b) is an electrostatic control gate and wherein:
step a) includes making several temporary material portions over the substrate, and
step b) is implemented such that the electrostatic control gate covers several distinct faces of each of the temporary material portions, and
step c) includes etching all of the temporary material portions, and
step d) is implemented such that several first areas of the semiconductor layer are arranged in locations formed by etching of the temporary material portions, the first areas of the semiconductor layer forming several semiconductor portions arranged over the substrate and such that the electrostatic control gate covers several distinct faces of each of the first areas (122) of the semiconductor layer.

9. The method according to claim 6, wherein the gate formed in step b) is an electrostatic control gate further including a step of depositing a gate dielectric layer or a ferroelectric memory layer implemented:
between steps a) and b), over the temporary material portion, the electrostatic control gate being made afterwards over the gate dielectric layer or the ferroelectric memory layer, and/or
between steps c) and d), beneath the electrostatic control gate and the dielectric spacers, in at least one location formed by etching of the temporary material portion, the semiconductor layer being made afterwards by covering the gate dielectric layer or the ferroelectric memory layer.

10. The method for making a FET microelectronic device according to claim 6, wherein the gate made in step b) is a temporary gate and wherein after step b) and before step e), etching of the temporary gate is performed, and an electrostatic control gate is made instead of the temporary gate.

11. The method according to claim 10, further including, before implementation of step c), depositing an insulating dielectric material around the dielectric spacers, then etching cavities in the insulating dielectric material such that the cavities comprise at least one lateral wall formed by one of the dielectric spacers, and wherein:
step d) is implemented such that the second areas of the semiconductor layer cover at least part of the lateral walls of the cavities;
step e) is implemented such that each of the source/drain regions is arranged in one of the cavities.

12. The method according to claim 9, wherein:
step a) includes making several temporary material portions over the substrate, and
step b) is implemented such that the temporary gate covers several distinct faces of each of the temporary material portions, and
step c) includes etching all of the temporary material portions, and
step d) is implemented such that several first areas of the semiconductor layer are arranged in locations formed by etching of the temporary material portions, the first areas of the semiconductor layer forming several semiconductor portions arranged over the substrate and such that the temporary gate covers several distinct faces of each of the first areas of the semiconductor layer.

13. The method according to claim 10, further including a step of depositing a gate dielectric layer or a ferroelectric memory layer implemented:
during step e), over the first area of the semiconductor layer, the electrostatic control gate being made afterwards over the gate dielectric layer or the ferroelectric memory layer, and/or
between steps c) and d), beneath the temporary gate and the dielectric spacers, in at least one location formed by etching of the temporary material portion, the semiconductor layer being made afterwards by covering the gate dielectric layer or the ferroelectric memory layer.

14. The method according to claim 6, further comprising, before making the electrostatic control gate, forming a gate dielectric layer or a ferroelectric memory layer, the electrostatic control gate being deposited over the gate dielectric layer or over the ferroelectric memory layer.

15. The method according to claim 6, wherein: forming the source/drain regions in step e) comprises making contacts each arranged in a cavity, the cavity comprising lateral walls and a bottom, the second areas of the semiconductor layer entirely covering the lateral walls and the bottom of the cavity, so that said contacts are entirely surrounded by the second areas of the semiconductor layer in their respective cavities.

16. The method according to claim 15, wherein the lateral walls of the cavities are formed partially by a dielectric spacer and partially by an insulating dielectric material.
